(19) United States
(12) Patent Application Publication
(10) Pub. No.: US 2006/0279323 A1
(43) Pub. Date: Dec. 14, 2006

(54) Power apparatus for dividing high voltage

(75) Inventor: Jong-hwa Cho, Suwon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/362,104

(22) Filed: Feb. 27, 2006

(30) Foreign Application Priority Data
Jun. 14, 2005 (KR) 10-2005-0051132

(51) Int. Cl. G01R 31/36

(52) U.S. Cl. 324/771

(57) ABSTRACT

A power apparatus and method of use is provided for dividing a high voltage for a device such as a laser printer and a laser multifunctional peripheral device, and includes a dividing unit which divides an input voltage of a high voltage signal into a predetermined ratio and outputs the divided voltage, a monitoring unit which receives a signal of the divided voltage output from the dividing unit and monitors the divided voltage, and a display unit which displays a voltage corresponding to the voltage monitored in the monitoring unit. Thus, a high voltage generated inside devices such as a printer can be monitored without using separate equipment for measuring a high voltage. In particular, when a high voltage output of an image outputting system is suspicious, the status of the output voltage can be simply checked using the power apparatus. Consequently, maintenance and repair of the printer during processes of developing or mass producing the printer can be conveniently performed. Furthermore, a unit is provided to notify a user or the printer of an error, such as the generation of an abnormal voltage.

### CROSS-REFERENCE TO RELATED APPLICATIONS

This application claims the benefit under 35 U.S.C. §119(a) of Korean Patent Application No. 10-2005-0051132, filed in the Korean Intellectual Property Office on Jun. 14, 2005, the entire disclosure of which is incorporated herein by reference.

### BACKGROUND OF THE INVENTION

1. Field of the Invention

The present invention relates to a power apparatus. More particularly, the present invention relates to a power apparatus for dividing high voltage through which operating or error status of the power apparatus can be easily known, the power apparatus being used in, for example, a laser printer or a laser multifunctional peripheral device.

2. Description of the Related Art

A high voltage power supply in a laser printer generates and outputs high voltage needed to form an image during a transfer process in response to a high/low signal or a pulse-width modulation (PWM) signal of an engine controller after receiving an input voltage of 24V from a switching mode power supply (SMPS) and a mainboard. The high voltage power supply outputs a received DC input voltage of 24V, as a high voltage output of hundreds or thousands of volts using a transformer.

FIG. 1 is a diagram illustrating a structure of a conventional high voltage power supply.

The conventional high voltage power supply comprises an input unit 110 having an RC low pass filter (not shown) which changes a PWM pulse signal into DC voltage after receiving a PWM duty or on/off signal from a CPU 100, an OP-AMP control unit 120 which compares a signal that passed the RC low pass filter with a reference signal, a TRANS and switching unit 130 which switches the compared output signal converted into a transistor driving signal and converts the driving signal into high voltage, a rectifying unit 140 which rectifies the output high voltage, a final output unit 150, and a feedback unit 160 which stabilizes the output by feeding back the output signal to the OP-AMP control unit 120.

The input unit 110 receives the PWM duty signal or the on/off signal output from the CPU or controller 100, and converts the signal into a DC level via the RC low pass filter. The DC level and a reference signal are input to the OP-AMP control unit 120 to generate an input signal for a transistor driving circuit to control the size of the output voltage. The input signal controls the base current of a main controller to control a time constant and the output of a primary coil of an oscillation circuit of a transformer, and an AC voltage at a secondary coil of the transformer is output as a DC voltage at the final output unit 150 by the rectifier of the rectifying unit 140. The rectifier of the rectifying unit 140 outputs positive (+) or negative (−) high voltages according to the direction of a diode in the rectifier of the rectifying unit 140.

There can be many reasons as to why a poor image is developed in laser-type office automation equipment using such a high voltage power supply. An image formed in an electrophotographic process is highly dependent on a high voltage power. If the high voltage power is not output normally, a poor image can be developed. Also, when examining the high voltage power supply to find out the reason for poor image development, special measuring equipment is required.

The same applies when determining whether or not high voltage is output normally, besides checking poor image development.

A user as well as an after-sale service mechanic, cannot determine the status of a high voltage power supply without the help of special equipment. In particular, where special equipment is unavailable, a unit related to the high voltage power supply is first exchanged with the questionable supply for providing quick repair services. This is very inconvenient and inefficient.

Therefore, a need exists for a system and method of easily determining the status of the high voltage power supply without using separate equipment.

### SUMMARY OF THE INVENTION

Embodiments of the present invention substantially solve the above and other problems, and provide a power apparatus for dividing a high voltage that can simply and reliably determine the presence of a high voltage power error.

According to an aspect of the present invention, a power apparatus is provided for dividing a high voltage for a device such as a laser printer and a laser multifunctional peripheral device. The power apparatus comprises a dividing unit which divides the input of a high voltage into a predetermined ratio and outputs the divided voltage.

The power apparatus may further comprise a monitoring unit which receives the divided voltage output by the dividing unit and monitors the divided voltage, and a display unit which displays a voltage corresponding to the voltage monitored in the monitoring unit.

The monitoring unit may determine that an overvoltage is output if the monitored divided voltage is higher than a first predetermined value and displays the result via the display unit. The monitoring unit may also determine that the monitored divided voltage is in an abnormal status if the monitored divided voltage is substantially near 0 volts and displays the result via the display unit. The monitoring unit may also determine that a low voltage is output if the monitored divided voltage is lower than a second predetermined value and displays the result via the display unit.

In this case, the monitoring unit may output an error signal to the power apparatus if the overvoltage or the low voltage is output or if the abnormal status is maintained for a predetermined period of time, and may warn a user of an operating status of the power apparatus.

### BRIEF DESCRIPTION OF THE DRAWINGS

The above and other features and advantages of the present invention will become more apparent by describing in detail exemplary embodiments thereof with reference to the attached drawings, in which:

FIG. 1 is a diagram illustrating a structure of a conventional high voltage power supply;

FIG. 2 is a block diagram of a power apparatus for dividing a high voltage according to an embodiment of the present invention; and

FIG. 3 is a diagram illustrating a structure of a power apparatus for dividing a high voltage according to another embodiment of the present invention.

Throughout the drawings, like reference numerals will be understood to refer to like parts, components and structures.

### DETAILED DESCRIPTION OF EXEMPLARY EMBODIMENTS

The present invention will now be described more fully with reference to the accompanying drawings, in which exemplary embodiments of the present invention are shown.

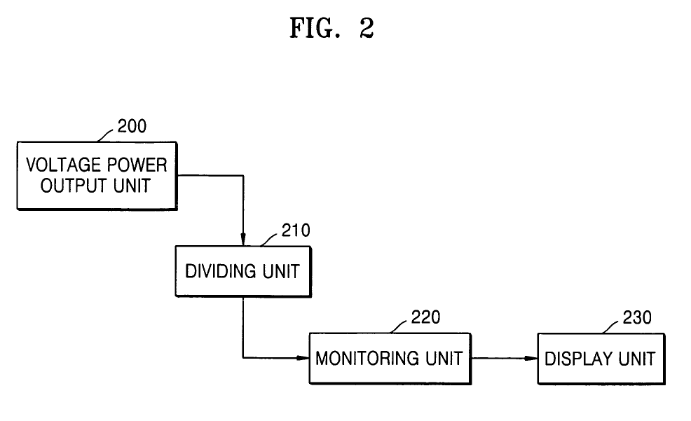

FIG. 2 is a block diagram of a power apparatus for dividing a high voltage according to an embodiment of the present invention.

The power apparatus which internally generates high voltage for a device, such as a laser printer and a laser multifunctional peripheral device, comprises a dividing unit 210 which receives a high voltage signal output by a voltage power output unit 200, divides the high voltage signal according to a predetermined ratio and outputs a divided voltage, a monitoring unit 220 which receives the divided voltage output by the dividing unit 210 and monitors the divided voltage, and a display unit 230 which displays a value corresponding to the voltage monitored by the monitoring unit 220.

Developing devices such as laser printers, laser multifunctional peripheral devices, and laser faxes, need a high voltage to deposit toners. For example, a charger needs −1,200 to −1,600 volts, a developing process requires −200 to −600 volts, and a transfer process requires 300 to 5,000 volts.

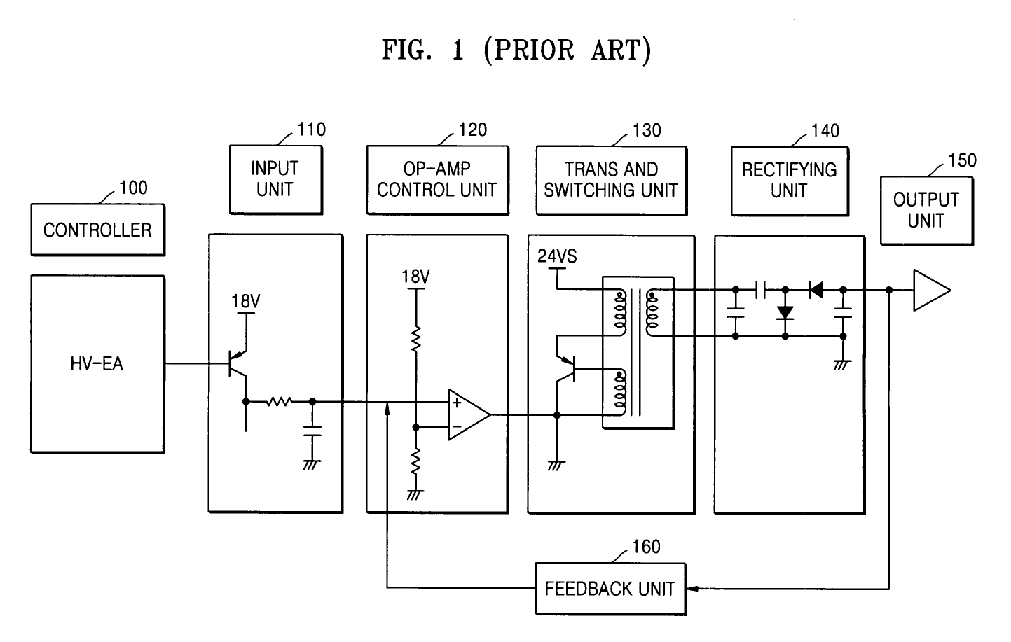

The voltage power output unit 200 internally generates and outputs such high voltages, and developing devices use the high voltages when needed. An example of the voltage power output unit 200 is illustrated in FIG. 1.

The dividing unit 210 receives the high voltage signal output as described above and divides the voltage, thereby reducing the voltage value. The reduced voltage value is not simply reduced to any volts but is reduced to a voltage related to a voltage of an input signal of the dividing unit 210. For example, the voltage of 5,000 volts is not simply divided into a signal having 5 volts, but is divided into a signal having a voltage of 1/1,000th of 5,000 volts.

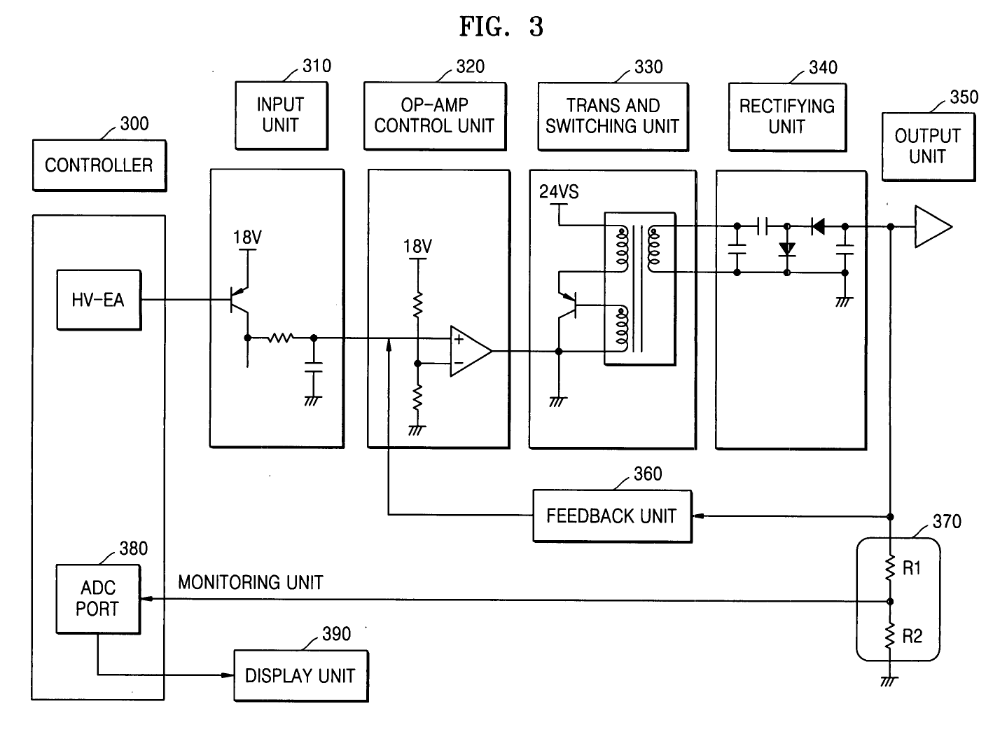

The voltage can be divided using a dividing resistance, but is not limited thereto. This is described in greater detail below with reference to FIG. 3.

The monitoring unit 220 monitors the divided voltage, and the divided and monitored voltage is displayed via the display unit 230. The monitoring unit 220 may include a function for converting an input analog voltage into a digital voltage that can be displayed via the display unit 230. The conversion of the analog voltage into the digital voltage can be performed in many ways, which can be easily configured by one of ordinary skill in the art to which the present invention pertains. Thus, their descriptions will be omitted.

When a voltage of a signal output by the voltage power output unit 200 is 5,000V and the ratio of dividing the voltage in the dividing unit 210 is 1/1,000 for example, the monitoring unit 220 monitors a voltage of 5V, and depending on the circumstances, 5,000V or 5V is displayed in the display unit 230.

The display unit 230 can be configured in, for example, a laser printer and can display a voltage value corresponding to a currently detected voltage while using the laser printer or in response to a separate function key.

When a user or an after-sales service mechanic presses a separate function key when there is an error in the laser printer, a voltage currently generated in the laser printer can be known, and thus, it can be determined whether or not there is an error in a portion where a high voltage is generated.

As in the example mentioned above where devices in which −1,200 to −1,600 volts, −200 to −600 volts, and 300 to 5,000 volts are internally generated, an abnormal error occurs when a voltage exceeding a maximum voltage or a voltage less than a minimum voltage is generated. An abnormal voltage is also generated if a voltage of near 0 volts is generated, and thus, the devices cannot operate normally.

In such cases, the monitoring unit 220 can determine that an overvoltage is output when the monitored divided voltage exceeds a first predetermined value and displays the result via the display unit 230.

Also, the monitoring unit 220 can determine an abnormal status when the monitored divided voltage is near or equal to 0 volts and/or determine that a low voltage is output if the monitored divided voltage is less than a second predetermined value and respectively output the result via the display unit 230.

In the above-described example in which the voltage is divided by 1000, the monitoring unit 220 monitors normal signals in the ranges of −1.200 to −1.600 volts, −0.200 to −0.600 volt, and 0.300 to 5.000 volts. If a voltage higher than 5 volts is monitored, an overvoltage indicating an abnormal status is generated and is displayed via the display unit 230.

Of course, there can be an error and yet many devices can still operate normally even if a voltage higher or lower than their proper voltage is input. Therefore, the first predetermined value should be determined considering such an error range, qualities or abilities to endure overvoltage, and so forth.

When the monitored voltage is substantially equal to 0 volts, that is, near 0 volts, a normal voltage is not generated, that is, the voltage power output unit 200 is considered to be not operating normally. This situation is displayed via the display unit 230 to prevent the user from operating the printer.

As in the case of the description regarding the overvoltage, the monitored voltage should preferably be determined to be near 0 volts by considering the error range.

In the above example, a low voltage is generated when a voltage lower than −1.2 volts is monitored, and thus, this is displayed via the display unit 230. Although it is said to be a “low voltage”, this is an expression considering only the detected value, and the “low voltage” is actually, in this case, a high voltage.

The second predetermined value may be determined by considering an error range, qualities or abilities to endure overvoltage, and so forth, as in the case of the overvoltage.

Furthermore, in all of the cases described above, the abnormal voltage can further refer to a value sustained for a predetermined time and not incidental values. Therefore, although not described separately, the abnormal status can be displayed considering the duration of the abnormal voltage.

In the above example, there are intermediate voltage ranges at which voltages are not generated. The voltages in the intermediate voltage ranges are also abnormal voltages. However, the abnormal voltage range can be different depending on the type of devices in which embodiments of the present invention are applied. Also, abnormal voltages can be detected when voltages change from one normal voltage range to another. Therefore, the abnormal status can be further defined considering the above-described cases.

In an abnormal state, a device such as a printer using the power apparatus of embodiments of the present invention cannot operate normally. If the abnormal state is maintained, a significant strain is put on the printer, thereby causing the printer to malfunction. Therefore, the operation of the printer should preferably be stopped if the abnormal state is maintained for a predetermined period of time. To do this, the monitoring unit 220 can warn the user of the operating status of the printer by outputting an error signal if the overvoltage or the low voltage is output or when the abnormal state is maintained for a predetermined period of time.

In this case, the error may be notified by outputting an interrupt signal as the error signal. The printer can respond to the interrupt signal by operating accordingly with a service routine set in advance regarding the interrupt signal.

In particular, an error related to power is a fatal error, in which case, the interrupt signal may be a non-maskable interrupt (NMI) signal.

FIG. 3 is a diagram illustrating a structure of a power apparatus for dividing a high voltage according to another embodiment of the present invention. FIG. 3 illustrates a power apparatus of an embodiment of the present invention included in a conventional power apparatus for providing a high voltage illustrated in FIG. 1.

The power apparatus comprises an input unit 310 having an RC low pass filter (not shown) which changes a pulse-width modulation (PWM) pulse signal into a DC voltage after receiving a PWM duty signal or an on/off signal from a CPU or controller 300, an OP-AMP control unit 320 which compares a signal output by the RC low pass filter with a reference signal, a TRANS and switching unit 330 which switches the compared output signal converted into a transistor driving signal and converts the driving signal into a high voltage, a rectifying unit 340 which rectifies the high output voltage, a final output unit 350, and a feedback unit 360 which stabilizes the output by feeding back the output to the OP-AMP control unit 320.

The high output voltage signal is input to a dividing unit 370 and is reduced by voltage dividing resistors R1 and R2. In this case, the voltage is divided by a constant ratio according to the ratio of R1 to R2. Although only two resistors are shown in the dividing unit 370, the present invention is not limited thereto.

The divided voltages are input to a monitoring unit 380 including an analog-to-digital converter (ADC) port of the CPU 300 and are monitored after being converted into digital values. The result of the monitoring is then displayed via a display unit 390.

In this scheme, the operation of the monitoring unit 380 is controlled by a CPU 300 controlling program.

Descriptions regarding the operations of the CPU 300, the input unit 310, the OP-AMP control unit 320, the TRANS and switching unit 330, the rectifying unit 340, the output unit 350, and the feedback unit 360, will be omitted as they are substantially the same as those described with reference to FIG. 1.

Dividing resistances are set by presetting resistance values of the resistors R1 and R2 of the dividing unit 370 so that, for example, a voltage of 1,000:1 regarding the output voltage signal is output to the monitoring unit 380. The voltage output from the output unit 350 is known in advance and resistance ratios of the resistors R1 and R2 can be determined by deciding appropriate dividing ratios regarding the voltage output from the output unit 350.

The voltage divided by the dividing unit 370 is fed back to the ADC port of the CPU 300. That is, when analog data corresponding to the voltage in a predetermined range is transmitted to the CPU 300 after the high output voltage is reduced by the dividing unit 370, the monitoring unit 380 including the ADC port of the CPU 300, reads the analog data and displays the current output in a digitalized form. As in the example described above, if the fed back analog voltage is 1.5V, 1,500V can be displayed via the display unit 390. Also, as previously described, the voltage can be displayed during a printing process or by pressing a separate operation key.

Alternatively, the voltage can be displayed via a monitor of a computer connected to the printer or a panel of the printer.

In particular, when an abnormal high voltage or 0 voltage is generated, the power apparatus according to embodiments of the present invention acts as an overvoltage and/or an undervoltage protecting apparatus.

According to embodiments of the present invention, an apparatus, such as a laser printer and a laser multifunctional peripheral device, comprises a dividing unit which divides the input of a high voltage into a predetermined ratio and outputs the divided voltage, a monitoring unit which receives a signal of the divided voltage output from the dividing unit and monitors the divided voltage, and a display unit which displays a voltage corresponding to the voltage monitored in the monitoring unit. Thus, a high voltage generated inside devices such as a printer can be monitored without using special equipment for measuring a high voltage. In particular, when a high voltage output from an image outputting system is suspicious, the status of the output voltage can be simply checked using embodiments of the present invention. Consequently, maintenance and repair of the printer during processes for developing or mass producing the printer can be conveniently performed. Furthermore, a unit can be provided to notify a user or the printer of an error, such as the generation of an abnormal voltage, depending on which method is adopted to increase convenience.

Also, as known to those of ordinary skill in the art, the present invention can be embodied in various ways as software or hardware using a general programming method.

Furthermore, some parts of the present invention can be embodied as computer readable codes on a computer readable recording medium. The computer readable recording medium can comprise any data storage device that can store data which can be thereafter read by a computer system.

While the present invention has been particularly shown and described with reference to exemplary embodiments thereof, it will be understood by those of ordinary skill in the art that various changes in form and detail may be made therein without departing from the spirit and scope of the invention as defined by the appended claims. The exemplary embodiments should be considered in descriptive sense only and not for purposes of limitation. Therefore, the scope of the invention is defined not by the detailed description of the invention but by the appended claims, and all differences within the scope will be construed as being included in the present invention.

What is claimed is:

1. A power apparatus for dividing a high voltage in a device such as a laser printer and a laser multifunctional peripheral device, the power apparatus comprising:
a dividing unit which divides the input of a high voltage into a predetermined ratio and outputs the divided voltage.

2. The power apparatus of claim 1, further comprising:
a monitoring unit which receives the divided voltage output by the dividing unit and monitors the divided voltage; and
a display unit which displays a voltage corresponding to the voltage monitored in the monitoring unit.

3. The power apparatus of claim 2, wherein the monitoring unit is configured to determine that an overvoltage is output if the monitored divided voltage is higher than a first predetermined value and display the result via the display unit.

4. The power apparatus of claim 2, wherein the monitoring unit is configured to determine that the monitored divided voltage is in an abnormal status if the monitored divided voltage is substantially 0 volts and display the result via the display unit.

5. The power apparatus of claim 2, wherein the monitoring unit is configured to determine that a low voltage is output if the monitored divided voltage is lower than a second predetermined value and display the result via the display unit.

6. The power apparatus of claim 2, wherein the monitoring unit is configured to output an error signal if the overvoltage or the low voltage is output or if the abnormal status is maintained for a predetermined period of time and warn of an operating status of the power apparatus.

7. The power apparatus of claim 6, wherein the monitoring unit is configured to output the error signal to the power apparatus.

8. A method for dividing a high voltage in a device such as a laser printer and a laser multifunctional peripheral device, comprising:
dividing the input of a high voltage into a predetermined ratio and outputting the divided voltage;
monitoring the divided voltage; and
displaying a voltage corresponding to the voltage monitored.

9. The method of claim 8, further comprising:
determining that an overvoltage is output if the monitored divided voltage is higher than a first predetermined value and displaying the result via the display unit.

10. The method of claim 8, further comprising:
determining that the monitored divided voltage is in an abnormal status if the monitored divided voltage is substantially 0 volts and displaying the result via the display unit.

11. The method of claim 8, further comprising:
determining that a low voltage is output if the monitored divided voltage is lower than a second predetermined value and displaying the result via the display unit.

12. The method of claim 8, further comprising:
providing an error signal if the overvoltage or the low voltage is output or if the abnormal status is maintained for a predetermined period of time; and
warning of an operating status of the power apparatus.

13. A computer program embodied on a computer-readable medium for dividing a high voltage in a device such as a laser printer and a laser multifunctional peripheral device, comprising:
a first set of instructions for dividing the input of a high voltage into a predetermined ratio and outputting the divided voltage;
a second set of instructions for monitoring the divided voltage; and
a third set of instructions for displaying a voltage corresponding to the voltage monitored.

14. The computer program embodied on a computer-readable medium of claim 13, further comprising:
a set of instructions for determining that an overvoltage is output if the monitored divided voltage is higher than a first predetermined value and displaying the result.

15. The computer program embodied on a computer-readable medium of claim 13, further comprising:
a set of instructions for determining that the monitored divided voltage is in an abnormal status if the monitored divided voltage is substantially 0 volts and displaying the result.

16. The computer program embodied on a computer-readable medium of claim 13, further comprising:
a set of instructions for determining that a low voltage is output if the monitored divided voltage is lower than a second predetermined value and displaying the result.

17. The computer program embodied on a computer-readable medium of claim 13, further comprising:
a set of instructions for providing an error signal if the overvoltage or the low voltage is output or if the abnormal status is maintained for a predetermined period of time and warning of an operating status of the power apparatus.
